(19) United States
(12) Patent Application Publication
(10) Pub. No.: US 2007/0037371 A1
(43) Pub. Date: Feb. 15, 2007

(54) Method of forming gate electrode structures

(76) Inventors: Zhigang Wang, Sunnyvale, CA (US); Nian Yang, Mountain View, CA (US); Shenqing Fang, Fremont, CA (US)

Correspondence Address: WILLIAMS, MORGAN & AMERSON, 10333 RICHMOND, SUITE 1100, HOUSTON, TX, 77042, US

(21) Appl. No.: 11/201,042

(22) Filed: Aug. 10, 2005

(51) Int. Cl. H01L 21/3205

(52) U.S. Cl. 438/585

(57) ABSTRACT

In one example, the method includes forming a patterned hard mask feature above a layer of gate electrode material, the hard mask feature having a photoresist feature formed thereabove and the hard mask feature having a critical dimension. The method further includes performing an etching process on the patterned hard mask feature to produce a reduced hard mask feature having a critical dimension that is less than the critical dimension of the patterned hard mask feature and performing an anisotropic etching process on the layer of gate electrode material using the reduced hard mask feature as a mask to define a gate electrode.

### BACKGROUND OF THE INVENTION

1. Field of the Invention

The present invention is generally related to the field of manufacturing integrated circuit devices, and, more particularly, to a method of forming gate electrode structures.

2. Description of the Related Art

There is a constant drive within the semiconductor industry to increase the operating speed of integrated circuit devices, e.g., microprocessors, memory devices, and the like. This drive is fueled by consumer demands for computers and electronic devices that operate at increasingly greater speeds. This demand for increased speed has resulted in a continual reduction in the size of semiconductor devices, e.g., transistors. That is, many components of a typical field effect transistor (FET), e.g., channel length, junction depths, gate insulation thickness, and the like, are reduced. For example, all other things being equal, the smaller the channel length of the transistor, the faster the transistor will operate. Thus, there is a constant drive to reduce the size, or scale, of the components of a typical transistor to increase the overall speed of the transistor, as well as integrated circuit devices incorporating such transistors.

The formation of gate electrode structures for transistors and memory devices is a critical aspect as it relates to the ultimate performance of the completed integrated circuit device. For example, for MOS transistors, the width or critical dimension of the gate electrode structure is a dominant factor in establishing the channel length of the completed transistor. Thus, integrated circuit manufacturers expend a great deal of resources in attempting to insure that the processes used to form gate electrode structures produce resulting structures having the desired critical dimension and cross-sectional configuration. Accurately forming gate electrode structures to desired target dimensions is even more difficult as the channel length of present-day, high performance transistors may be less than 80 nm [?], and further reduction in channel length are anticipated on future device generations.

FIGS. 1A-1C depict an illustrative prior art process flow that is employed to form gate electrode structures. As depicted in FIG. 1A, a gate insulation layer 12, e.g., silicon dioxide, is formed on a surface 11 of a semiconducting substrate 10. A layer of gate electrode material 14, e.g., polysilicon, is deposited above the gate insulation layer 12. An illustrative photoresist feature 16 is formed above the layer of gate electrode material 14. The various layers depicted in FIG. 1A may be formed by performing a variety of known processing techniques, e.g., thermally growing the gate insulation layer 12, depositing the gate electrode material layer 14 by performing a CVD process, and creating a patterned layer of photoresist comprising the feature 16 using known photolithography techniques.

In some applications, the formation of gate electrode structures involves an initial photoresist trim step to reduce the size of the photoresist feature 16 prior to performing an etching process on the underlying layer of gate electrode material 14. The photoresist trim process may be employed to produce finished gate electrode structures that have a critical dimension beyond the resolution capability of the photolithography equipment used in producing the photoresist feature 16. FIG. 1B depicts a trimmed photoresist feature 16A after the trimming process is performed. Note that the critical dimension 15A of the trimmed photoresist feature 16A is less than the critical dimension 15 of the original photoresist feature 16.

As indicated in FIG. 1C, the next step involves performing an etching process on the layer of gate electrode material 14 using the trimmed photoresist feature 16A as a mask. This results in the formation of a gate electrode structure 14A. However, it should be noted that the gate electrode structure 14A has outwardly flared sidewalls 19 due to the photoresist material lost during the trimming process. This flaring is sometimes referred to as “footing.” Footing is undesirable in that it makes it difficult to reliably and repeatedly manufacture gate electrode structures to desired target dimensions. Moreover, footing increases the effective critical dimension of the gate electrode structure 14A. These issues are even more problematic as targeted critical dimensions for gate electrode structures continue to shrink.

The present invention is directed to a device and various methods that may solve, or at least reduce, some or all of the aforementioned problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present invention is generally directed to various methods of forming gate electrode structures. In one illustrative embodiment, the method comprises forming a patterned hard mask feature above a layer of gate electrode material, wherein a photoresist feature is formed above the patterned hard mask feature. The method further includes performing an etching process on the patterned hard mask feature to produce a reduced hard mask feature having a critical dimension that is less than the critical dimension of the patterned hard mask feature and performing an anisotropic etching process on the layer of gate electrode material using the reduced hard mask feature as a mask to define a gate electrode.

In another illustrative embodiment, the method comprises forming a layer of gate electrode material above a semiconducting substrate, forming a hard mask layer above the layer of gate electrode material and forming a photoresist feature above the hard mask layer. The method further comprises performing an anisotropic etching process to pattern the hard mask layer using the photoresist feature as a mask, the etching process defining a patterned hard mask feature having a critical dimension, performing an isotropic etching process on the patterned hard mask feature to define a reduced hard mask feature having a critical dimension that is less than the critical dimension of the patterned hard mask feature, and performing an anisotropic etching process on the layer of gate electrode material using the reduced hard mask feature as a mask to define a gate electrode.

In yet another illustrative embodiment, the method comprises depositing a layer of gate electrode material comprised of polysilicon above a semiconducting substrate, depositing a hard mask layer comprised of silicon nitride on the layer of gate electrode material and forming a photoresist feature on the hard mask layer. The method further comprises performing an anisotropic etching process to pattern the hard mask layer using the photoresist feature as a mask, the etching process defining a patterned hard mask feature having a critical dimension, performing an isotropic etching process on the patterned hard mask feature with the photoresist feature on the patterned hard mask feature to define a reduced hard mask feature having a critical dimension that is less than the critical dimension of the patterned hard mask feature, and performing an anisotropic etching process on the layer of gate electrode material using the reduced hard mask feature as a mask to define a gate electrode having substantially vertical sidewalls relative to a surface of the substrate.

### BRIEF DESCRIPTION OF THE DRAWINGS

The invention may be understood by reference to the following description taken in conjunction with the accompanying drawings, in which like reference numerals identify like elements, and in which:

FIGS. 1A-1C are cross-sectional views depicting one illustrative prior art process flow for forming a gate electrode structure; and

FIGS. 2A-2D are cross-sectional views depicting formation of a gate electrode structure in accordance with one illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these structures may not be as precise as indicated in the drawings. Additionally, the relative sizes of the various features depicted in the drawings may be exaggerated or reduced as compared to the size of those features on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

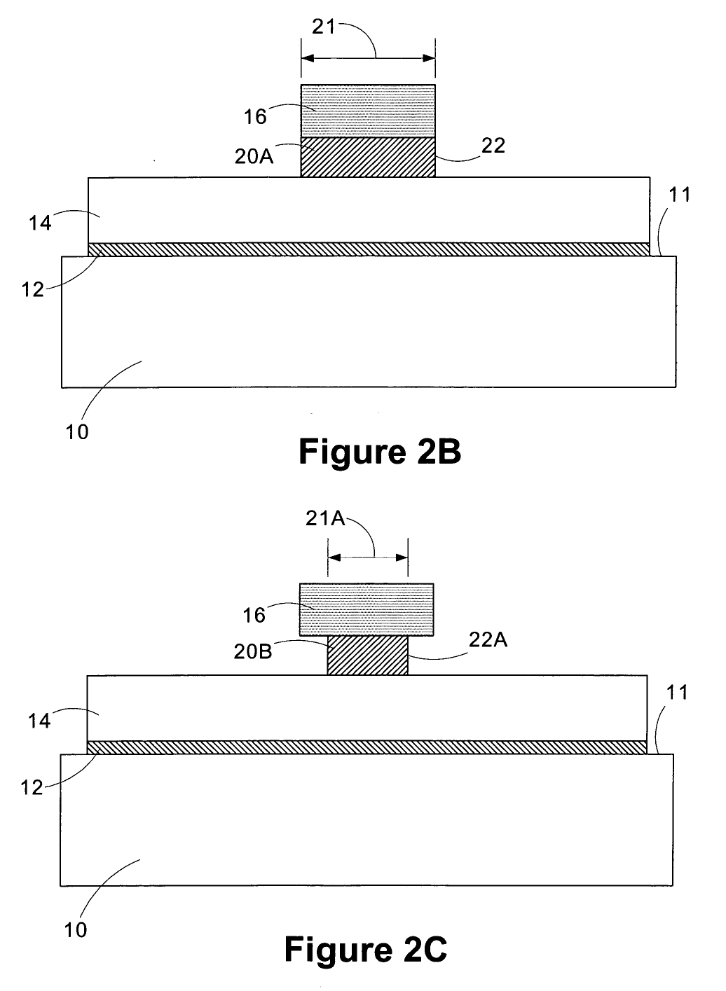

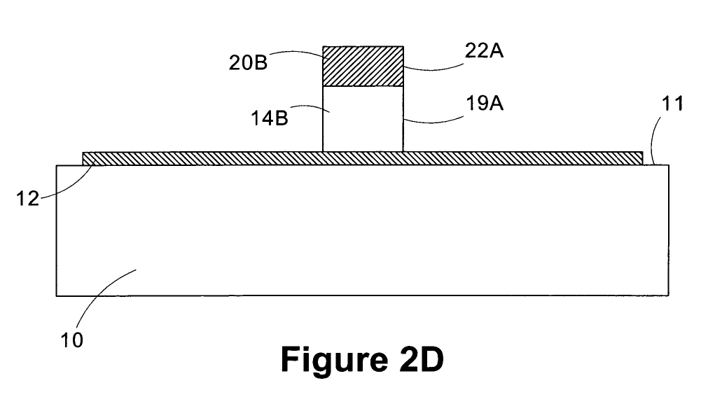

FIGS. 2A-2D depict one illustrative process flow for forming a gate electrode structure in accordance with one aspect of the present invention. As will be understood by those skilled in the art after a complete reading of the present application, the present invention has broad applicability. Thus, the present invention should not be considered as limited to the illustrative embodiments and examples disclosed herein.

FIG. 2A depicts a stage of manufacturing wherein a gate insulation layer 12, a layer of gate electrode material 14, a hard mask layer 20 and a patterned photoresist feature 16 have been formed above a semiconducting substrate 10. The substrate 10 may be comprised of a variety of materials, e.g., silicon, gallium arsenide, etc. The substrate 10 may be in bulk form or it may be the active layer of a silicon-on-insulator (SOI) substrate.

The various layers depicted in FIG. 2A may be formed using a variety of known techniques. For example, the gate insulation layer 12 may be comprised of a variety of materials, e.g., silicon dioxide, silicon oxynitride, and high-k dielectric materials such as tantalum oxide, etc., and it may be formed by performing known thermal growth or deposition processes. In one illustrative embodiment, the gate insulation layer 12 is comprised of a thermally grown layer of silicon dioxide having a thickness of approximately 15-100 Å.

The layer of gate electrode material 14 may also be comprised of a variety of materials, e.g., polysilicon, tungsten silicide, aluminum, etc., and it may be formed by performing any of a variety of known deposition processes, e.g., a low pressure chemical vapor deposition (LPCVD) process. In one illustrative embodiment, the layer of gate electrode material 14 is comprised of polysilicon and it has a thickness of approximately 500-2000 Å.

The hard mask layer 20 may be formed from a variety of materials, and it may be formed using a variety of techniques. By use of the term “hard mask layer,” it is meant that the layer is comprised of a solid state material other than a photoresist material. For example, the hard mask layer 20 may be comprised of silicon nitride, silicon-rich nitride, silicon oxynitride, silicon dioxide, or any solid state insulator materials with a high selectivity with respect to the gate electrode below it. The hard mask layer 20 may be formed by performing a variety of known deposition processes, e.g., an LPCVD process. In one illustrative embodiment, the hard mask layer 20 is a layer of silicon nitride formed by an LPCVD process having a thickness of approximately 600-1400 Å. Of course, additional layers of material may be present if desired. For example, an anti-reflective coating (ARC) layer (not shown) may be formed on the layer of gate electrode material 14. Thus, the presence of additional layers of material is readily contemplated by the present invention.

The photoresist feature 16 is part of a patterned layer of photoresist material that is formed above the hard mask layer 20 using known photolithography tools and techniques. The photoresist feature 16 may be comprised of either a positive or negative photoresist material depending upon the particular application.

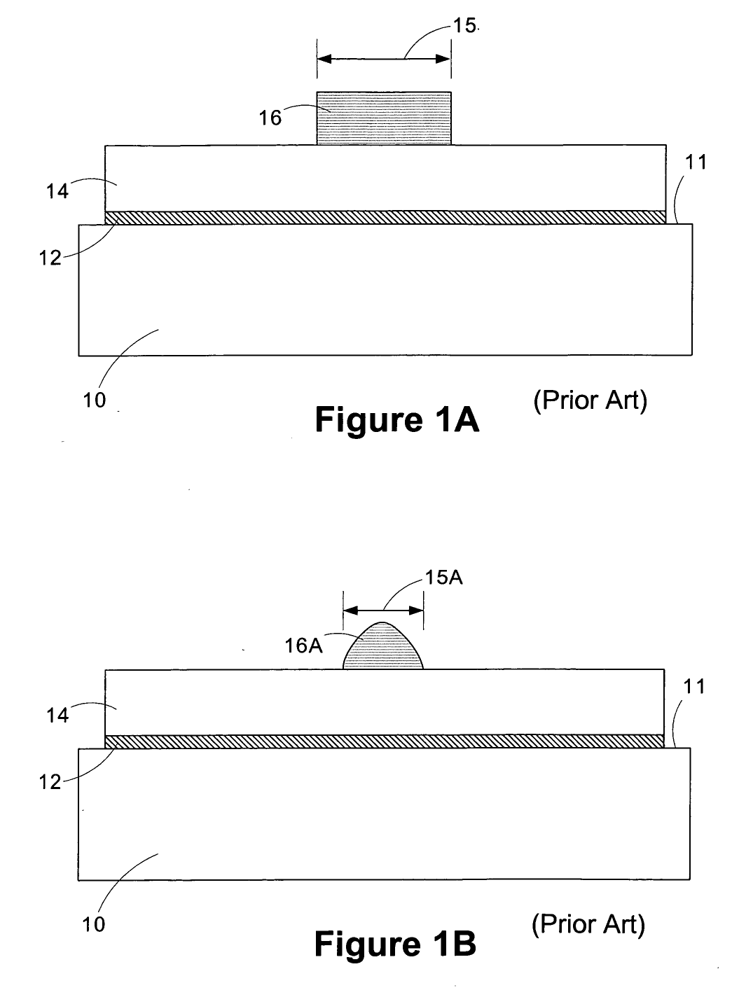

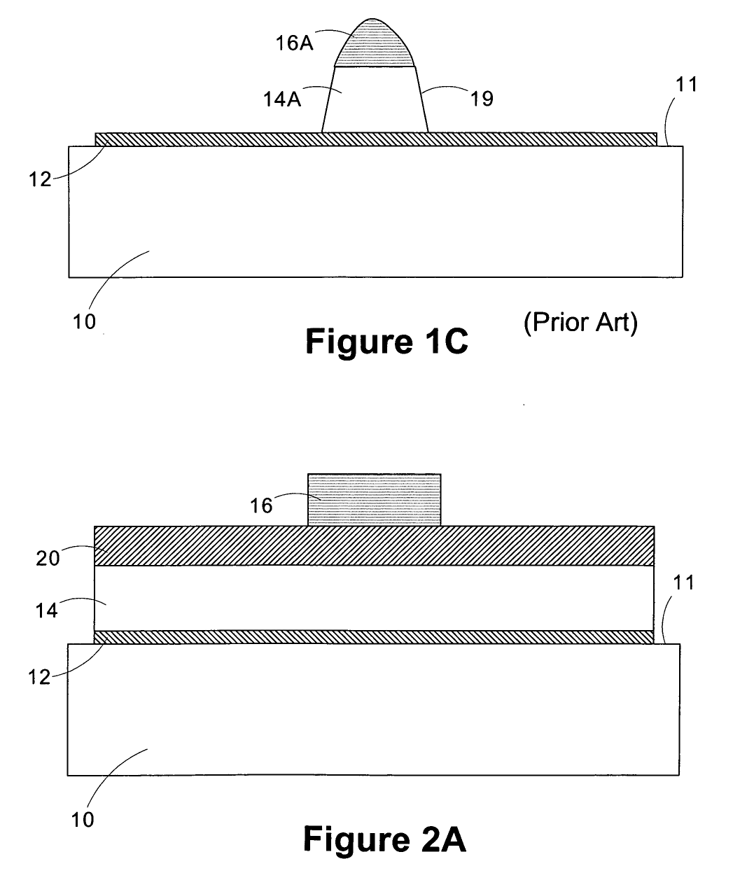

After the structure depicted in FIG. 2A is formed, an etching process is performed to etch the hard mask layer 20 to thereby define a hard mask feature 20A, as shown in FIG. 2B. More specifically, an anisotropic etching process is performed to etch the hard mask layer 20 using the photoresist feature 16 as a mask. The hard mask feature 20A has a critical dimension 21 that corresponds approximately to the critical dimension of the photoresist feature 16A. In one illustrative embodiment, the critical dimension 21 may be approximately 250-2000 Å. Note that the photoresist trimming process described above with respect to Figures 1A-1C is not performed prior to etching the hard mask layer 20. Due to the anisotropic nature of the etching process and the shape of the photoresist feature 16, the sidewalls 22 of the hard mask feature 20A are substantially vertical relative to the surface 11 of the substrate 10.

Next, as indicated in FIG. 2C, an isotropic etching process is performed to define a reduced hard mask feature 20B having a critical dimension 21A that is less than the critical dimension 21 of the hard mask feature 20A. In one illustrative embodiment, the critical dimension 21A of the reduced hard mask feature 20B may be approximately 200-1500 Å. The final dimension 21A of the reduced hard mask feature 20B may be controlled by controlling the duration of the isotropic etching process. Since etching rates of various material/etchant combinations are well known, the final critical dimension 21A may be precisely controlled to achieve desired target dimensions.

The isotropic etching process may be, for example, a wet etching process using the appropriate etchant. For example, in the case where the hard mask layer 20 is comprised of silicon nitride, a wet etching process using HNO₃ may be used to produce the reduced hard mask feature 20B. Note that, due to the isotropic nature of the etching process, the sidewalls 22A of the reduced hard mask feature 22B are also substantially vertical relative to the surface of the substrate 10.

Next, as indicated with reference to FIG. 2D, the photoresist feature 16 is removed by performing a variety of known techniques, e.g., ashing. Thereafter, an anisotropic etching process is performed on the layer of gate electrode material 14 using the reduced hard mask feature 20B as a mask. This results in the definition of a gate electrode structure 14B having substantially vertical sidewalls 19A. As will be recognized by those skilled in the art after a complete reading of the present application, the methodologies disclosed herein may help to reduce or prevent the “footing” of gate electrode structures, like that described with reference to FIG. 1C. After the gate electrode 14B is formed, traditional manufacturing operations may be performed to complete the transistor or memory device.

The present invention is generally directed to various methods of forming gate electrode structures. In one illustrative embodiment, the method comprises forming a patterned hard mask feature above a layer of gate electrode material, wherein a photoresist feature is formed above the patterned hard mask feature. The method further includes performing an etching process on the patterned hard mask feature to produce a reduced hard mask feature having a critical dimension that is less than the critical dimension of the patterned hard mask feature and performing an anisotropic etching process on the layer of gate electrode material using the reduced hard mask feature as a mask to define a gate electrode.

In another illustrative embodiment, the method comprises forming a layer of gate electrode material above a semiconducting substrate, forming a hard mask layer above the layer of gate electrode material and forming a photoresist feature above the hard mask layer. The method further comprises performing an anisotropic etching process to pattern the hard mask layer using the photoresist feature as a mask, the etching process defining a patterned hard mask feature having a critical dimension, performing an isotropic etching process on the patterned hard mask feature to define a reduced hard mask feature having a critical dimension that is less than the critical dimension of the patterned hard mask feature, and performing an anisotropic etching process on the layer of gate electrode material using the reduced hard mask feature as a mask to define a gate electrode.

In another illustrative embodiment, the method comprises depositing a layer of gate electrode material comprised of polysilicon above a semiconducting substrate, depositing a hard mask layer comprised of silicon nitride on the layer of gate electrode material and forming a photoresist feature on the hard mask layer. The method further comprises performing an anisotropic etching process to pattern the hard mask layer using the photoresist feature as a mask, the etching process defining a patterned hard mask feature having a critical dimension, performing an isotropic etching process on the patterned hard mask feature with the photoresist feature on the patterned hard mask feature to define a reduced hard mask feature having a critical dimension that is less than the critical dimension of the patterned hard mask feature, and performing an anisotropic etching process on the layer of gate electrode material using the reduced hard mask feature as a mask to define a gate electrode having substantially vertical sidewalls relative to a surface of the substrate.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a patterned hard mask feature above a layer of gate electrode material, said patterned hard mask feature having a photoresist feature formed thereabove, said patterned hard mask feature having a critical dimension;
performing an etching process on said patterned hard mask feature to produce a reduced hard mask feature having a critical dimension that is less than said critical dimension of said patterned hard mask feature; and
performing an anisotropic etching process on said layer of gate electrode material using said reduced hard mask feature as a mask to define a gate electrode.

2. The method of claim 1, wherein said semiconducting substrate comprises silicon.

3. The method of claim 1, wherein forming said patterned hard mask feature comprises:
depositing a hard mask layer above said layer of gate electrode material;
forming a patterned layer of photoresist comprising said photoresist feature above said hard mask layer; and
etching said hard mask layer using said patterned layer of photoresist as a mask to thereby define said patterned hard mask feature.

4. The method of claim 1, wherein said patterned hard mask feature comprises at least one of silicon nitride, silicon-rich nitride, silicon oxynitride and a solid state material having a high selectivity with respect to said gate electrode.

5. The method of claim 1, wherein said photoresist feature is positioned above said patterned hard mask feature during said step of performing said etching process on said patterned hard mask feature.

6. The method of claim 1, wherein said critical dimension of said patterned hard mask feature is approximately 250-2000 Å.

7. The method of claim 1, wherein said critical dimension of said reduced hard mask feature is approximately 200-1500 Å.

8. The method of claim 1, wherein said gate electrode has substantially vertical sidewalls relative to a surface of said substrate.

9. A method, comprising:
forming a layer of gate electrode material above a semiconducting substrate;
forming a hard mask layer above said layer of gate electrode material;
forming a photoresist feature above said hard mask layer;
performing an anisotropic etching process to pattern said hard mask layer using said photoresist feature as a mask, said etching process defining a patterned hard mask feature having a critical dimension;
performing an isotropic etching process on said patterned hard mask feature to define a reduced hard mask feature having a critical dimension that is less than said critical dimension of said patterned hard mask feature; and
performing an anisotropic etching process on said layer of gate electrode material using said reduced hard mask feature as a mask to define a gate electrode.

10. The method of claim 9, wherein said semiconducting substrate comprises silicon.

11. The method of claim 9, wherein forming said hard mask layer above said layer of gate electrode material comprises depositing said hard mask layer above said layer of gate electrode material.

12. The method of claim 9, wherein forming said hard mask layer above said layer of gate electrode material comprises forming said hard mask layer comprised of at least one of silicon nitride, silicon-rich nitride, silicon oxynitride and a solid state material having a high selectivity with respect to said gate electrode above said layer of gate electrode material.

13. The method of claim 9, wherein forming said hard mask layer above said layer of gate electrode material comprises forming said hard mask layer on said layer of gate electrode material.

14. The method of claim 9, wherein forming said photoresist feature above said hard mask layer comprises forming said photoresist feature on said hard mask layer.

15. The method of claim 9, wherein said critical dimension of said patterned hard mask feature is approximately 250-2000 Å.

16. The method of claim 9, wherein said critical dimension of said reduced hard mask feature is approximately 200-1500 Å.

17. The method of claim 9, wherein said gate electrode has substantially vertical sidewalls relative to a surface of said substrate.

18. The method of claim 9, wherein said step of performing said isotropic etching process on said patterned hard mask feature to define a reduced hard mask feature is performed with said photoresist feature positioned above said patterned hard mask feature.

19. A method, comprising:
depositing a layer of gate electrode material above a semiconducting substrate;
depositing a hard mask layer above said layer of gate electrode material;
forming a photoresist feature on said hard mask layer;
performing an anisotropic etching process to pattern said hard mask layer using said photoresist feature as a mask, said etching process defining a patterned hard mask feature having a critical dimension;
performing an isotropic etching process on said patterned hard mask feature with said photoresist feature on said patterned hard mask feature to define a reduced hard mask feature having a critical dimension that is less than said critical dimension of said patterned hard mask feature; and
performing an anisotropic etching process on said layer of gate electrode material using said reduced hard mask feature as a mask to define a gate electrode.

20. The method of claim 19, wherein forming a hard mask layer above said layer of gate electrode material comprises forming a hard mask layer comprised of at least one of silicon nitride, silicon-rich nitride, silicon oxynitride and a solid state material having a high selectivity with respect to said gate electrode above said layer of gate electrode material.

21. The method of claim 19, wherein depositing said hard mask layer above said layer of gate electrode material comprises depositing said hard mask layer on said layer of gate electrode material.

22. A method, comprising:
depositing a layer of gate electrode material comprised of polysilicon above a semiconducting substrate;
depositing a hard mask layer comprised of silicon nitride on said layer of gate electrode material;
forming a photoresist feature on said hard mask layer;
performing an anisotropic etching process to pattern said hard mask layer using said photoresist feature as a mask, said etching process defining a patterned hard mask feature having a critical dimension;
performing an isotropic etching process on said patterned hard mask feature with said photoresist feature on said patterned hard mask feature to define a reduced hard mask feature having a critical dimension that is less than said critical dimension of said patterned hard mask feature; and
performing an anisotropic etching process on said layer of gate electrode material using said reduced hard mask feature as a mask to define a gate electrode having substantially vertical sidewalls relative to a surface of said substrate.
